(19) United States
(12) Patent Application Publication
(10) Pub. No.: US 2012/0318332 A1
(43) Pub. Date: Dec. 20, 2012

(54) System And Method For A Networked Solar Panel Railroad Infrastructure

(75) Inventor: John Cooper, Elizabethton, TN (US)

(73) Assignee: John Cooper, Elizabethton, TN (US)

(21) Appl. No.: 13/163,714

(22) Filed: Jun. 19, 2011

(51) Int. Cl. H01L 31/048; H01L 31/18

(52) U.S. Cl. 136/251; 29/428

(57) ABSTRACT

A Solar Panel design that can be inserted between railroad tracks of existing and future infrastructure. The design may include rubber mounting brackets (or a similar design for vibration reduction) to mount and/or attach the solar panels to the existing and/or planned railroad ties that run perpendicular to the railroad track. The solar panels may contain conduits for fiber optic line, copper line, coaxial line and other transmission lines. Power may be transferred panel to panel through the physical connection between the panels or by use of a cable or similar that will connect the panels, thus creating a nested infrastructure and smart power grid. The solar panels can be made in different lengths, widths, dimensions, and shapes, including as a curved panel in order to trace along current and/or planned railroad lines. The top of the solar panels may be made of a durable glass/plastic substrate or similar material.

### FIELD OF THE INVENTION

This invention relates to the utilization of current existing and future railroad infrastructure to provide an environmentally sustainable power source.

### BACKGROUND OF THE INVENTION

It is well known that solar power is derived from photovoltaic systems, solar panels made from silicon, and from other materials and thin film solar deployments. An ‘array’ of solar panels tied together with one or more solar power gathering devices is an environmentally sustainable method of generating clean energy that can be used internationally. Solar power generation can come from thin film solar applications, panelized silicon crystal applications, and also from passive solar design schemes and many other sources. The cost of solar power gathering systems have decreased in recent years, and their efficiency continues to improve.

Currently, solar power creates less than ten percent of the energy market share in the United States. The vast majority of solar power installations have been used to power individual homes and businesses by using solar panel installations on such building structures. Such uses of solar power are effective but is an example of incremental installation. The solar power is isolated to a particular building and does not create an effective solar infrastructure. Solar power plants are becoming more popular and new isolated site power plants are being developed in places like the Mojave Desert near Blythe, Calif. where a 3,000 Megawatt solar power plant is currently being federally funded which will take up nearly 8,000 acres. Isolated solar power panels are also in use on roadways to light signs, lights and power emergency telephones and telephone boxes.

The idea of powering individual homes and businesses, while effective, amounts to only incremental gains in terms of solar power distribution and use of solar power. The same can be said for privately funded solar power plants. This is because many of them must be built in remote, sunny, desert-like locations given their large size in terms of square footage. Consequently, access to the grid or direct power access to homes or businesses is difficult.

### SUMMARY OF INVENTION

In one embodiment, the invention includes a solar collecting system for generating electrical power comprising: at least one solar panel; the at least one solar panel being positioned between the rails of railroad tracks; wherein the at least one solar panel is affixed to railroad ties associated with the railroad tracks with vibration reduction brackets; and a means for collecting the electrical power from the at least one solar panel.

In another embodiment, the invention includes a method of collecting solar energy, the method comprising: locating at least one solar panel between rails of a railroad track; affixing the at least one solar panel to railroad ties of the railroad track with vibration reduction brackets; accumulating electrical power from the at least one solar panel; and transmitting the electrical power away from the location at which the solar energy was collected.

In another embodiment, the invention includes a method of preparing for the collection of solar energy, the method comprising: retrofitting railroad tracks to include at least one solar panel positioned between rails of the railroad tracks; affixing the at least one solar panel to railroad ties of the railroad track with vibration reduction brackets; providing a storage device for the accumulation of electrical power from the at least one solar panel; and providing a pathway for the transmission of the electrical power away from the location at which the solar energy was collected.

### BRIEF DESCRIPTION OF THE DRAWINGS

The drawings are meant to illustrate the principles of the invention and do not limit the scope of the invention. The above-mentioned features and objects of the present disclosure will become more apparent with reference to the following description taken in conjunction with the accompanying drawings wherein like reference numerals denote like elements in which:

FIG. 1 depicts an isometric view to show the possible location and spacing that can be obtained when placing the solar panels (110) on the railroad ties (105).

FIG. 2 depicts the side view with one railroad track removed to illustrate the side view to show the aspect ratio.

FIG. 3 depicts the front view to show some possible locations of the power connection socket (305), transmission line conduits (310) and vibration reduction mounts (205). FIG. 3 also shows the adequate clearance between the top of the solar panel (110) from the top of the railroad track (125).

### DETAILED DESCRIPTION OF THE DRAWINGS

Reference will now be made in detail to the exemplary embodiments of the present disclosure, examples of which are illustrated in the accompanying drawings, wherein like reference numerals refer to like elements throughout. The embodiments are described below so as to explain the present disclosure by referring to the figures. Repetitive description with respect to like elements of different exemplary embodiments may be omitted for the convenience of clarity.

The present invention includes a Solar Panel design that can be inserted between railroad tracks of existing and future infrastructure. The design may include rubber mounting brackets (or a similar design for vibration reduction) to mount and/or attach the solar panels to the existing and/or planned railroad ties that run perpendicular to the railroad track. The solar panels may contain conduits for fiber optic line, copper line, coaxial line and other transmission lines. Power may be transferred panel to panel through the physical connection between the panels or by use of a cable or similar that will connect the panels, thus creating a nested infrastructure and smart power grid. The solar panels can be made in different lengths, widths, dimensions, and shapes, including as a curved panel in order to trace along current and/or planned railroad lines. The top of the solar panels may be made of a durable glass/plastic substrate or similar material. The solar panels may include hydrophobic and/or anti-glare properties in the glass/plastic substrate (or similar) covering. The solar panels will rest between the two metal rails mounted to the railroad ties and be maintained low enough (that the top of the solar panels and the bottom most section of the railroad cars have adequate clearance) to provide an adequate clearance to allow railroad cars, both those used currently and in the future, to pass over the top without harming or interfering with either.

The proposed invention of solar energy being generated by use of railroad infrastructure—both existing, and that are built in the future—provides a solution to the limitations seen today of current solar power generation being created but limited to the generation of solar power for individual houses and commercial buildings only—and not tied to the power grid.

One embodiment of the present invention is a railway system for energy generation and distribution. The railway system includes a plurality of solar energy generating devices connected to an electric grid as well as a distribution network for fiber optic and other communications lines. The plurality of solar energy generating devices are configured to electrically connect to the railway system electricity grid and positioned in between the railroad ties. These solar energy-generating devices contain conduits for the passage of communication wires and a host of storage batteries to capture excess energy generation for use when the demand increases.

The individual solar panels may connect to each other to create an array; the connection can be as simple as GFI plug type, or a more complex design. The conduits may contain a set number of cables of multiple types for transmission of communication lines (fiber, copper, coaxial, etc.). Since each panel may be connected together in a series, a failure of one panel will not shut down the entire system. This creates a smart grid network within already developed railway lines throughout the world, and works well with any future developed railroad tracks.

To ensure longevity, the solar panels may be fixed to the railroad ties using a rubber-mounting bracket (or similar design for vibration reduction) to minimize the transmission of vibrations from railroad cars passing over. These panels may also be used to provide heating elements to the railroad tracks to provide de-icing characteristics during the cooler months. This will allow for a more efficient railway system when adverse conditions arise.

Calculating possible total energy production from the nested solar panel arrays within existing railroad infrastructure is as follows:

The US standard gauge regarding the distance between railroad tracks is 4 feet. For calculation of total possible power generation, a solar panel width of 3 feet and 6 inches is used as a standard width. This takes into account a clearance that may be required for railroad car wheels. There are approximately 233,000 miles of railroad tracks in the United States alone. This amounts to 154.5 square miles of possible solar panel coverage on existing railroad tracks. Using a commercially available solar power efficiency of 19.3%, this solar power efficiency is currently the highest possible available efficiency on a commercially produced solar panel on the market today. Using existing infrastructure in this manner is the most cost-effective way to produce large-scale, commercial solar energy. Some simple math can provide an illustration of possible wattage available in pristine conditions. These panels produce 18 W peak power per square feet of surface area. As the technology improves the efficiency will also improve.

((154.5 mi²)×(5280 ft/mi)²)/(1 ft²/18 W)=((154.5 mi²)×(27,878,400 ft²/mi²))/(1 ft²/18 W)=(807424257024 ft²)/(13.4 ft²/230 W)=4,307,212,800 Watts or over 4.3 Billion Kilowatts

If we use an average of only 4 hours of peak daylight hours (taking into consideration the angle of the sun and the change in seasons), that accounts for 1460 hours of peak sunlight over a year. This would provide 4,307,212,800×1460 hours=6,288,530,688,000 Kilowatt-Hours or 6.29 Billion Kilowatt-Hours of electricity.

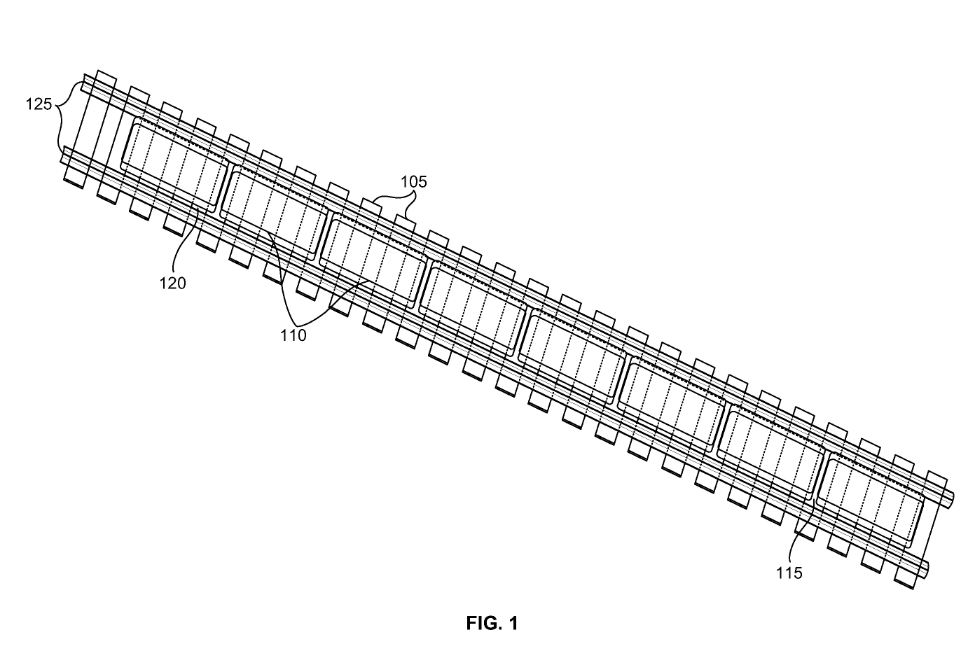

Railroad ties (105), from FIG. 1, are typically spaced equal distances from each other. This spacing will make it easier to mass produce solar panels (110) of certain length to enable quick installation and replacement or damaged components. The solar panels can be made to provide a minimal amount of space between each other (115) or to have no space at all which will maximize the total amount of surface area to be utilized. The isometric view of the solar panels (110) arranged on the railroad ties (105) shows that there is adequate vertical clearance (120) that can be obtained from the railroad tracks (125) to enable current rail cars to use the tracks without any modification necessary. The solar panels (110) can be at different lengths to minimize the number of panels required to stretch longer straight distances. The solar panel structure will be designed such that it will last long periods of time without needing to be replaced. The solar cells themselves will need to be replaced after a set number of years. This design will also allow the solar cells to be replaced with more efficient cells as they become available in the future. This will also minimize the cost associated with replacement since the entire structure will not be to be replaced.

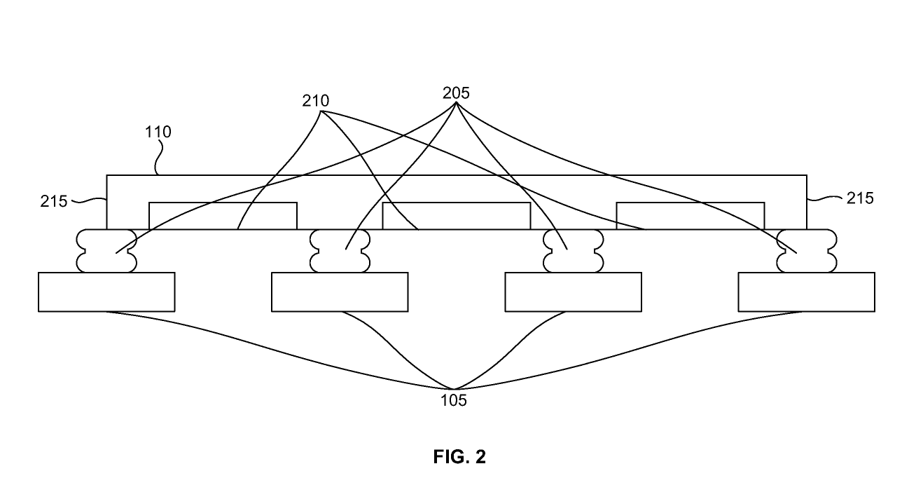

The side view FIG. 2 shows how the solar panels (110) can be attached to the railroad ties (105) using a mounting system (205) for vibration reduction. These vibrations reduction mounts (205) can be placed on every railroad tie (105) or spaced out evenly among the railroad ties (105) to minimize the number of contact points with the railroad system. The solar panels (110) can be constructed to have wells (210) for battery placement, electronic hardware, or even simply to clear some obstructions on the railroad ties (105) themselves. The end of the solar panels (215) can be made to mount on half of a vibration mount (205) such that the next connecting solar panel will share the same mount. This can be utilized to ensure that the solar panels remain connected and will minimize the chance of the power/cable connections from coming apart.

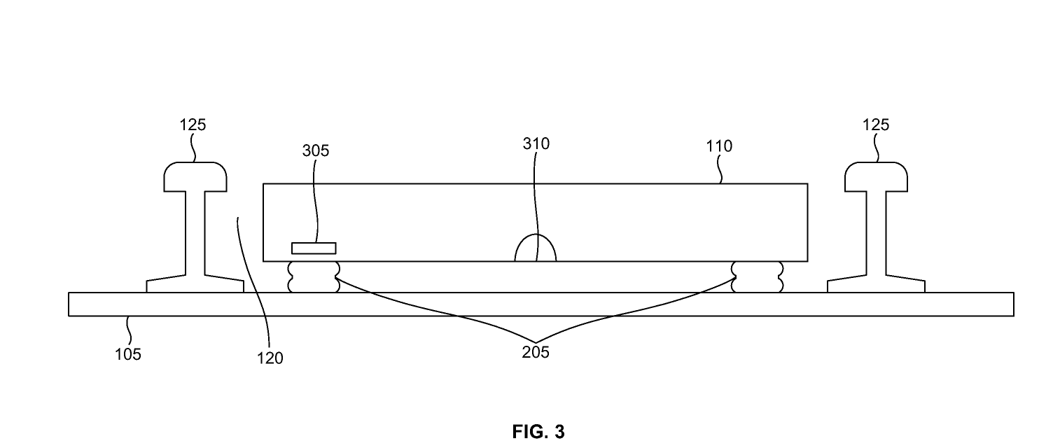

The end view FIG. 3 shows how the solar panels (110) can be utilized to provide an adequate clearance gap (120) between the solar panel (110) and the railroad track (125). The vibration reduction mounts (205) can be placed anywhere along the length of the railroad tie (105) that will provide the most vibration reduction. The most likely position would be closer to the center of the railroad ties (105) so it can be utilized furthest away from the railroad track (125). The solar panel (110) will maintain a connection to the each other by a power connection (305) on either end of the solar panel (110). This power connection (305) can be a simplistic GFI connection to a more complex connection that will hold together more robustly should a vibration reduction mount (205) deteriorate and no longer provide reduction. The cable tunnel (310) can be used to route numerous types of communication cables. This system can be used to bring high speed internet, fiber optic cable, and other communication lines to rural areas located along the railroad system. The location of the cable tunnel (310) can be located anywhere along the length of the solar panel (110). The utilization of the solar panel (110) can enable to power generated by the system to power the converters to increase the signal strength that can be lost over long cable runs. It may be a small step to providing rural communities with high speed Internet and other communication options but it most definitely is a good start. FIG. 3 also illustrates a clearance between the top of the solar panel (110) and the top of the railroad track (125).

1. A solar collecting system for generating electrical power comprising:
at least one solar panel;
said at least one solar panel being positioned between the rails of railroad tracks;
wherein said at least one solar panel is affixed to railroad ties associated with said railroad tracks with vibration reduction brackets;
and a means for collecting the electrical power from said at least one solar panel.

2. The solar collecting system of claim 1, wherein more than one solar panel is connected to form a solar array.

3. The solar collecting system of claim 1, wherein each solar panel includes an electrical power storage device.

4. The solar collecting system of claim 1 wherein a portion of said electrical power is used to prevent the formation of ice or used to remove ice that has formed on said rails.

5. The solar collecting system of claim 1 wherein at least one solar panel includes a conduit for the transmission of said electrical power.

6. The solar collecting system of claim 5 wherein said conduit contains transmission lines of data.

7. The solar collecting system of claim 1 wherein at least one solar panel includes a surface with hydrophobic or anti-glare properties.

8. A method of collecting solar energy, said method comprising:
locating at least one solar panel between rails of a railroad track;
affixing said at least one solar panel to railroad ties of said railroad track with vibration reduction brackets;
accumulating electrical power from said at least one solar panel; and
transmitting said electrical power away from the location at which the solar energy was collected.

9. The method of claim 8, wherein more than one solar panel is connected to form a solar array.

10. The method of claim 8, wherein each solar panel includes an electrical power storage device.

11. The method of claim 8 wherein a portion of said electrical power is used to prevent the formation of ice or used to remove ice that has formed on said rails.

12. The method of claim 8 wherein at least one solar panel includes a conduit for the transmission of said electrical power.

13. The method of claim 12 wherein said conduit contains transmission lines of data.

14. The method of claim 8 wherein at least one solar panel includes a surface with hydrophobic or anti-glare properties.

15. A method of preparing for the collection of solar energy, said method comprising:
retrofitting railroad tracks to include at least one solar panel positioned between rails of said railroad tracks;
affixing said at least one solar panel to railroad ties of said railroad track with vibration reduction brackets;
providing a storage device for the accumulation of electrical power from said at least one solar panel; and
providing a pathway for the transmission of said electrical power away from the location at which the solar energy was collected.

16. The method of claim 15, wherein more than one solar panel is connected to form a solar array.

17. The method of claim 15, wherein each solar panel includes an electrical power storage device.

18. The method of claim 15 wherein a portion of said electrical power is designed to be used to prevent the formation of ice or used to remove ice that has formed on said rails.

19. The method of claim 15 wherein at least one solar panel includes a conduit for the transmission of said electrical power.

20. The method of claim 15 wherein at least one solar panel includes a surface with hydrophobic or anti-glare properties.
